(19) United States
(12) Patent Application Publication
(10) Pub. No.: US 2015/0340426 A1
(43) Pub. Date: Nov. 26, 2015

(54) COMPONENT, FOR EXAMPLE NMOS TRANSISTOR, WITH AN ACTIVE REGION UNDER RELAXED COMPRESSIVE STRESS, AND ASSOCIATED DECOUPLING CAPACITOR

(71) Applicant: STMICROELECTRONICS (ROUSSET) SAS, Rousset (FR)

(72) Inventors: Sylvie Wuidart, Pourrieres (FR); Christian Rivero, Rousset (FR); Guilhem Bouton, Peynier (FR); Pascal Fornara, Pourrieres (FR)

(73) Assignee: STMICROELECTRONICS (ROUSSET) SAS, Rousset (FR)

(21) Appl. No.: 14/715,814

(22) Filed: May 19, 2015

(30) Foreign Application Priority Data
May 21, 2014 (FR) 1454552

(51) Int. Cl. H01L 49/02; H01L 27/06; H01L 29/423; H01L 27/115; H01L 29/78

(52) U.S. Cl. CPC H01L 28/60; H01L 27/11524; H01L 27/11526; H01L 29/7842; H01L 29/42356; H01L 27/0629

(57) ABSTRACT

An integrated circuit includes a substrate and a circuit component (such as a MOS device or resistance) disposed at least partially within an active region of the substrate limited by an insulating region. A capacitive structure including a first electrode (for connection to a first potential such as ground) and a second electrode (for connection to a second potential such as a supply voltage) is provided in connection with the insulating region. One of the first and second electrodes is situated at least in part within the insulating region. The capacitive structure is thus configured in order to allow a reduction in compressive stresses within the active region.

### PRIORITY CLAIM

This application claims priority from French Application for Patent No. 1454552 filed May 21, 2014, the disclosure of which is incorporated by reference.

### TECHNICAL FIELD

The invention relates to integrated circuits, and more particularly, to the relaxing of the compressive stresses of an active region, for example that of an NMOS transistor, and also to the generation of embedded decoupling capacitors, in other words formed in conjunction with other components of the integrated circuit and on the same chip.

### BACKGROUND

In an integrated circuit, the transistors are formed in and on an active semiconductor region, for example of silicon, surrounded by an electrically-insulating region, for example a trench filled for example with silicon dioxide.

Forming an MOS transistor inside of an insulating region naturally leads to the formation of an active region under compressive stress owing to the presence at its periphery of the insulating region. Moreover, although an active region under compressive stress favors the performance of a PMOS transistor, on the contrary it leads to a degradation in the performance characteristics of an NMOS transistor, notably in terms of mobility of the carriers.

Furthermore, the fabrication of fast transistors imposes small channel lengths and widths and the structures generally formed have a high density, which leads to very small, or even minimal, dimensions of active regions for the technology in question.

It is therefore extremely difficult, or even impossible, to increase the dimensions of the active regions of NMOS transistors for the purposes of relaxing their compressive stresses, in view of the density sought for the structures formed.

Furthermore, in an integrated circuit, decoupling capacitors are highly recommended because they act as a local reservoir for charges, which reduces the internal noise and electromagnetic emissions. Normally, these capacitors are designed to be disposed in a “white space” of the integrated circuit, in other words in areas not occupied by elements of the circuit, available on the chip. However, this requires specific design work by the designer and, the majority of the time, only a small part of the white space is used.

### SUMMARY

According to one embodiment, the idea is to reduce as far as possible the compressive stresses in the active region of a component detrimentally sensitive to compressive stresses, for example an NMOS transistor, or else an active resistance, in other words formed within an active region, whose resistive value can vary with the compressive stresses, and this must be done without modifying the characteristics of the PMOS transistors, while at the same time enabling the formation of an embedded decoupling capacitor which is transparent for the designer of the integrated circuit.

According to one aspect, an integrated circuit is provided comprising a substrate and at least one component disposed at least partially within an active region of the substrate limited by an insulating region.

According to a general feature of this aspect, the integrated circuit furthermore comprises a capacitive structure having a first electrode designed to be connected to a first potential, for example ground, a second electrode designed to be connected to a second potential, for example a power supply voltage for the integrated circuit, one of the two electrodes being situated, at least in part, within the insulating region, in other words surrounded at least partially by a part of the insulating region; the capacitive structure is thus configured for allowing a reduction in compressive stresses within said active region.

The active region of the substrate within which is disposed the component is an active region under compressive stress owing to the presence of the insulating region. Indeed, generally speaking, the material forming the insulating region, for example silicon dioxide, exhibits a thermal expansion coefficient much lower than that of the material forming the active region, typically silicon. For this reason, at the end of the process of fabrication of the transistor, the insulating region is under compressive stress, consequently inducing compressive stresses within the active region.

Since at least one of the electrodes of the capacitive structure is situated, at least in part, within the insulating region, the capacitive structure used here therefore has a dual function, namely a function of an capacitor acting notably as a decoupling capacitor, but also a function for reducing the compressive stresses within said active region, which notably allows the mobility of the carriers of an NMOS transistor to be improved.

Furthermore, since at least one of the electrodes of the capacitive structure is situated, at least in part, within the insulating region, its formation, and as a consequence the formation of the capacitive structure, is totally transparent for the integrated circuit designer since the latter simply determines the dimensions of the active region and of the insulating region without worrying about the content of this insulating region and, potentially, about the content of the volume situated on top of this insulating region.

According to one embodiment, the other electrode may be formed by a part of the substrate or else be contained within the volume situated on top of the insulating region.

The component may advantageously be a component detrimentally sensitive to compressive stresses.

A component detrimentally sensitive to compressive stresses is notably a component at least one of whose characteristics is modified in the presence of compressive stresses leading to a degradation of its performance characteristics, as is the case for example for the mobility characteristic of an NMOS transistor.

The component detrimentally sensitive to the compressive stresses of its active region can be an NMOS transistor or else an active resistance in other words formed within said active region, without these two examples being limiting.

Generally, an integrated circuit furthermore comprises an additional insulating region, disposed above the component, the active region and the insulating region.

According to one variant, the first electrode comprises a first region formed by a part of the substrate and locally separating said insulating region into two insulating areas and the second electrode comprises an electrically-conducting second region, comprising for example polysilicon, situated in the additional insulating region on top of said separation region, the two electrodes being separated by a layer of a dielectric material, for example of silicon dioxide.

Thus, according to this variant, within the insulating region a separation wall is formed by a part of the substrate whose goal is to absorb a part of the stresses generated by the insulating region. Furthermore, since this wall, which is mechanically active, is formed within the insulating region, its formation is totally transparent for the designer of the integrated circuit since the latter simply determines the dimensions of the active region and of the insulating region without dealing with the content of this insulating region, in other words in this case, the presence of a wall within this insulating region. Furthermore, the definition of the location of this wall is advantageously carried out directly and automatically during the Boolean generation of the various levels used for the fabrication of the active mask region without intervention of the designer and without this separation wall interfering with the transistor for example.

Furthermore, since the electrically-conducting second region is situated on top of the separation region, and hence within the volume situated on top of this insulating region, its formation is here again totally transparent for the designer of the integrated circuit since the latter is not concerned with the content of the volume situated immediately above the insulating region. In addition, when this electrically-conducting second region comprises polysilicon, the definition of the location of this second region may advantageously be directly and automatically carried out during the generation of the “polysilicon” mask or “poly” mask, in other words the mask used for the definition of the gate regions notably of the transistors, without intervention of the designer and without this second region interfering with the transistor for example.

According to one embodiment, said separation region has an upper face situated substantially at the same level as said upper face of the active region and opens into a lower region of the substrate.

In other words, the depth of this separation wall is substantially equal to the depth of the insulating region.

In order to enable a more efficient relaxation of the compressive stresses in the active region, the insulating area situated nearest to said active region has a volume less than or equal to that of the insulating area furthest from the active region.

When the integrated circuit comprises an additional insulating region comprising a lower insulating layer (CESL layer for example) in compression disposed above the component, the active region and the insulating region, this lower insulating layer in compression above the transistor and the insulating region also contributes to the presence of the compressive stresses in the active region. Also, a relaxation of compressive stresses in said active region may be obtained by the second region (second electrode) which forms an outgrowth disposed on top of the first electrode (the separation wall) and underneath said lower insulating layer in compression.

In other words, this outgrowth locally raises said lower insulating layer in compression, which therefore allows the compressive stresses in said active region to be relaxed.

When the component is an NMOS transistor, said outgrowth advantageously has a structure analogous to that of the gate region of the transistor.

The power supply voltage can then for example be applied to this second electrode via a contact coming into contact with the upper part of this electrically-conducting second region, for example made of polysilicon.

The first electrode, in other words the separation region, can then be connected to ground.

According to another variant, the substrate forms the first electrode and the second electrode comprises an electrically-conducting trench situated at least in the insulating region and containing an internal area configured in order to allow a reduction in compressive stress within said active region, the second electrode being separated from the first electrode by a dielectric material.

Thus, the compressive stresses are reduced (these compressive stresses are relaxed) in the active region by reducing the compressive stresses in the insulating region owing to the presence of said electrically-conducting trench.

Furthermore, since this trench is formed within the insulating region, its formation is here again totally transparent for the designer of the integrated circuit since the latter simply determines the dimensions of the active region and of the insulating region without being concerned by the content of this insulating region, in other words in this case by the presence of an electrically-conducting trench within this insulating region.

This trench is mechanically active in order to allow a reduction in the compressive stresses, and electrically active because it is connected to the second potential, for example the power supply voltage.

The trench is advantageously separate from a part of the substrate.

According to one possible embodiment, the internal area may contain polycrystalline silicon or polysilicon. Indeed, such a material, obtained after re-crystallization of deposited amorphous silicon, is a material in tension which further facilitates the reduction of the compressive stresses within the insulating region and, as a consequence, within the active region. Furthermore, such an embodiment offers a thermo-mechanical advantage. This is because silicon and polysilicon have identical thermal expansion coefficients and this results in lower stresses within the active region when the temperature undergoes changes linked to the environment of the product incorporating the integrated circuit.

While the trench may only be situated within the insulating region, it can, according to one embodiment, have an upper part situated in the insulating region and extended by a lower part situated in the substrate and separated from the substrate by a layer of dielectric material, the internal area of the trench configured in order to allow a reduction in compressive stresses within said active region then being situated within the upper part and within the lower part.

With such an embodiment, a greater reduction in the compressive stresses is obtained.

According to one embodiment, the integrated circuit can comprise a memory device comprising a memory plane having non-volatile memory cells and selection transistors with buried gates, together with a control block for the memory plane notably comprising NMOS transistors forming the components detrimentally sensitive to the compressive stresses; said at least one electrically-active trench is then situated within at least the insulating region limiting the active region of at least one of these NMOS transistors of the control block and has a depth substantially equal to that of the buried gates.

### BRIEF DESCRIPTION OF THE DRAWINGS

Other advantages and features of the invention will become apparent upon examining the detailed description of embodiments, which are non-limiting, and the appended drawings in which:

FIG. 1 illustrates schematically an NMOS transistor of the prior art,

FIG. 2 illustrates one embodiment of an integrated circuit,

FIG. 3 illustrates schematically one embodiment of an insulating region according to the prior art,

FIG. 4 illustrates one embodiment of a method for formation of an insulating region, and

FIGS. 5 to 16 illustrate schematically various embodiments.

### DETAILED DESCRIPTION OF THE DRAWINGS

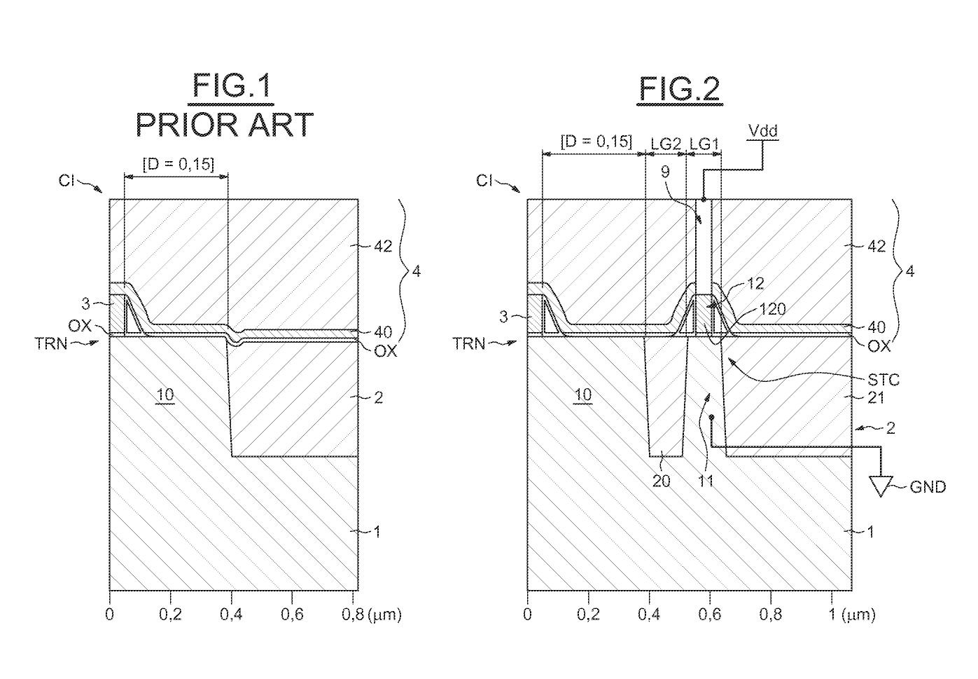

In FIG. 1, the reference TRN denotes an NMOS transistor whose active region 10 is situated within a semiconductor substrate 1, for example made of P-doped silicon. The active region is surrounded by an insulating region 2, for example of the shallow trench isolation (or STI) type.

The transistor TRN, forming part of an integrated circuit CI, conventionally comprises a gate region 3 separated from the active region 10 by a gate dielectric OX, for example silicon dioxide. Furthermore, the gate region 3, the active region 10 and the insulating region 2 are covered by the layer of gate dielectric OX and by an additional insulating region 4 conventionally comprising a lower insulating layer 40, for example of silicon nitride, also referred to by the those skilled in the art under the acronym CESL (Contact Etch Stop Layer). The additional insulating region 4 also comprises at least one other layer on top of the layer 40, for example at least one layer 42 of silicon dioxide.

For the purposes of simplification of the figure, the source and drain regions, situated within the active region and doped N, are not shown.

Here, the transistor TRN is formed using a 90 nanometer technology and the distance D between the gate region 3 and the insulating region 2, in other words the length of the source or drain region is here equal to 0.23 micrometers owing to the presence of a contact on this source or drain region.

When the component is a capacitor, this region 3 forms one electrode of the capacitor and the distance D can be brought down to 0.15 micrometers in the absence of the contact.

The insulating region 2 is generally made of silicon dioxide. In view of the fact that the thermal expansion coefficient of the active region 10 is greater than the thermal expansion coefficient of the insulating region 2, at the end of the process of fabrication, and notably during the cooling step, the silicon dioxide 2 will contract less than the silicon 10 of the active region leading to an insulating region 2 in compression and consequently inducing compressive stresses in the active region 10.

With respect to the transistor TRN in FIG. 1, the transistor TRN according to the embodiment illustrated in FIG. 2 comprises, within the insulating region 2, a separation region 11 formed by a part of the substrate 1, and separating the insulating region 2 into two insulating areas 20 and 21.

The separation region is also covered by the layer of gate dielectric OX.

Furthermore, the upper face of the separation wall 11 is situated substantially at the same level as the upper face of the active region 10 and this separation wall opens into the lower part of the substrate 1. Here, the width LG1 of the separation region 11 is equal to the critical dimension CD of the technology in question, in the present case 0.11 micrometers. This critical dimension is the minimum dimension of a line of active region.

Here, the width LG2 of the insulating area 20 is equal to the minimum spacing between two active regions defined by the DRM (Design Rules Manual) of the technology in question, in the present case 0.14 micrometers for a 90 nanometer technology.

This separation region absorbs the stresses produced by the insulating area 21 and, for this reason, the stresses in the active region 10 only essentially result from the insulating area 20 which has a reduced volume with respect to the total volume of the insulating region 2 in the configuration of the prior art illustrated in FIG. 1.

The presence of such a separation region already allows a gain in mobility of 20% to be obtained with respect to a conventional transistor TRN of the prior art such as that illustrated in FIG. 1.

The separation region 11 forms a first electrode of a capacitive structure STC.

The second electrode of this capacitive structure here comprises a second region or outgrowth 12 having an electrically-conducting central part 120, for example made of polysilicon, separated from the first electrode 11 by the layer of gate dielectric OX.

As illustrated in FIG. 2, when the component TRN is an NMOS transistor, the outgrowth 12 advantageously has a structure analogous to that of the gate region 3 of the transistor.

In the 90 nanometer technology for example, the minimum width of the central part of an outgrowth 12 is equal to 0.1 micrometers.

When the lower insulating layer 40 is a layer under compressive stress, the outgrowth 12 contributes to relaxing the stresses within the active region 10 of the transistor TRN because this outgrowth locally raises the lower insulating layer 40.

While the first electrode (separation region 11) is for example connected to ground, for example via a lateral contact region not shown in FIG. 2, the second electrode, in this case the central part 120 of the outgrowth 12, is for example connected to the power supply voltage Vdd.

This connection to the potential Vdd can be obtained in a simple fashion, as illustrated in FIG. 2, by a metal contact 9, for example made of tungsten, coming into contact with the summit of the central part 120 of the outgrowth 12.

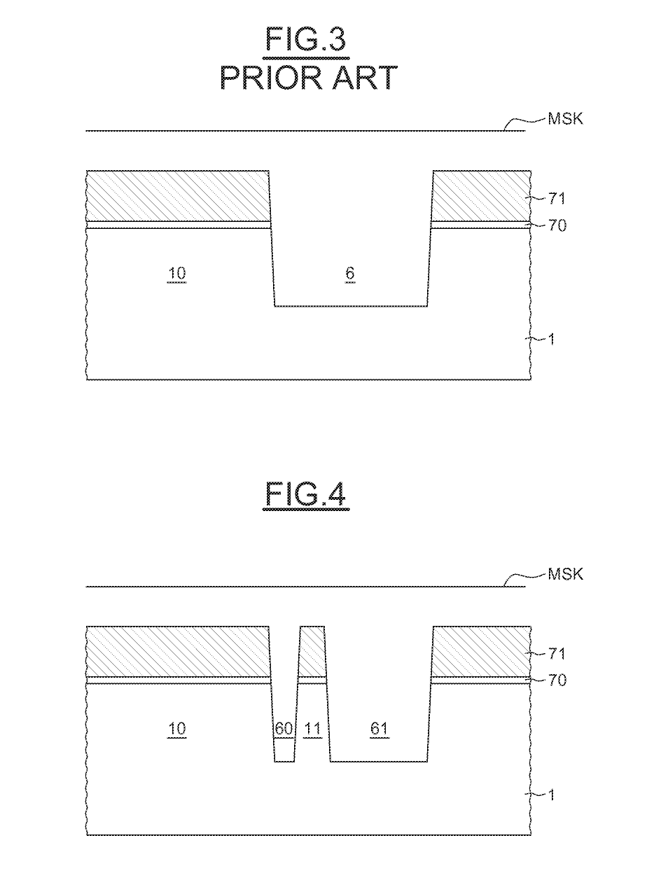

FIG. 3 illustrates schematically the formation of the insulating region 2 bounding the active region 10 of the transistor TRN in FIG. 1.

A bilayer 70 (silicon oxide/silicon nitride) is deposited onto the substrate 1 on which is a layer of photoresist 71 which is exposed through a mask MSK called “active mask” or “active region mask”, which will allow the determination of the contours of the insulating region 2 and consequently those of the active region. Then, after development of the resist, an etch of the bilayer 70 and of the substrate 1 is performed using the remaining part of the resist 71 as a hard mask so as to obtain a trench 6 which will be filled with insulating material so as to form the insulating region 2 of the transistor TRN.

With respect to this prior art, the method according to one embodiment of the invention includes (FIG. 4) the definition within the active mask MSK of the locations of the two insulating areas separated by the separation region (separation wall). More precisely, after exposure and development of the resist 71, on the bilayer 70 there subsists blocks of resist which will be used as hard masks for the formation of two trenches 60 and 61 in the bilayer 70 and the substrate 1. These two trenches are de facto separated by the separation wall 11 and will be filled with the insulating material so as to form the two insulating areas 20 and 21 of the transistor in FIG. 2.

It will be noted here that the trenches 60 and 61 are situated inside of the contour of the insulating region 6.

It is this contour which is defined by the designer when he/she defines the dimensions of the active regions. As a consequence, including within the mask MSK two trenches in this insulating region is totally transparent for the designer.

The definition of these trenches is advantageously carried out automatically during the Boolean generation of the levels used for the fabrication of the active mask taking into account the various aforementioned dimensions D, LG2, LG1.

Once the formation of the insulating areas 20 and 21 has been carried out, the layer of gate dielectric OX is formed over the whole of the integrated circuit and the later steps for fabrication of the integrated circuit are carried out in a conventional manner known per se, notably the formation of the gate regions of the transistors, of the lateral spacers of the layer 40 and of the insulating region 42.

The formation of the outgrowth 12 is carried out simultaneously with the formation of the gate region 3 and with fabrication steps identical to those used for the formation of this gate region.

More precisely, after having formed by deposition and etching the central part of the gate region 3 and the central part 120 of the outgrowth 12, these central parts are flanked with insulating lateral regions or spacers. Then, the additional insulating region 4 is formed with the lower layer 40 in compression.

The location and the geometry of the polysilicon central part 120 of the outgrowth 12 are defined within the “poly” mask used for defining the locations and geometries of the gate regions of the transistors.

Here again, this is carried out automatically without the intervention of the designer of the circuit and in a manner totally transparent to him/her.

The metal contact 9 is formed in an analogous manner to the metal contacts designed to come into contact with the source, drain and gate regions of the transistor in order to connect them to a metallization level of the interconnection part (BEOL: Back End Of Line) of the integrated circuit.

The location and the geometry of the contact 9 are defined on the “contacts” mask.

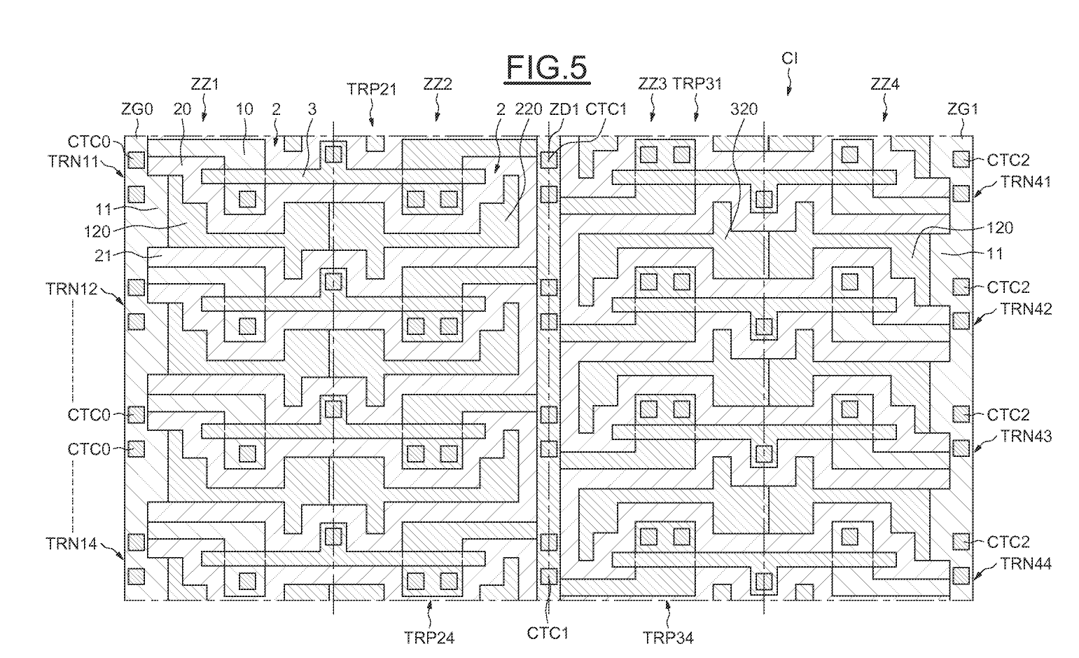

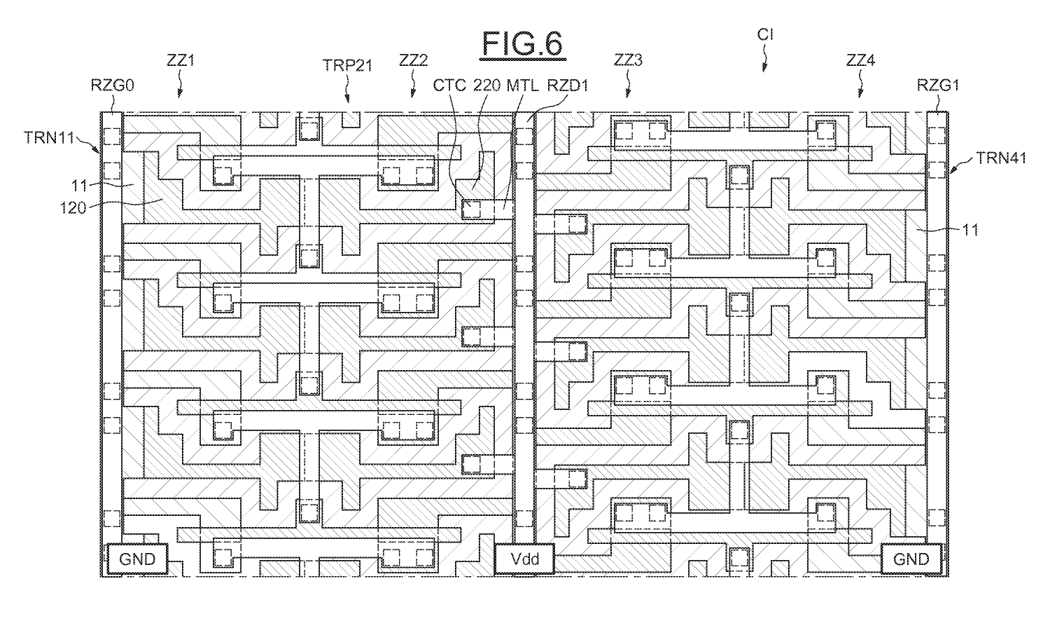

However, the use of a metal contact 9 coming into direct contact with the second electrode 120 of the capacitive structure is not the only possible solution for connecting this electrode to the power supply voltage Vdd as will now be explained in relation to FIGS. 5 and 6.

These figures are a partial representation of a ring oscillator formed within the integrated circuit CI.

The ring oscillator comprises, in the region ZZ1 of the integrated circuit, a series of NMOS transistors TRN11-TRN14 (only 4 are shown for the purposes of simplification) and, in the region ZZ2, a series of PMOS transistors TRP21-TRP24. These NMOS and PMOS transistors are connected together in a conventional manner known per se so as to form inverters.

Such a structure of inverters can be seen in the regions ZZ3 and ZZ4 of the integrated circuit respectively comprising the PMOS transistors TRP31-TRP34 and the NMOS transistors TRN41-TRN44.

The environment of the NMOS transistor TRN11 and of the PMOS transistor TRP21 will now more particularly be described, it being clearly understood that this environment is analogous for the other inverters of the oscillator.

The active region 10 of the transistor TRN11 is limited by the insulating region 2. The active region 10 comprises the source and drain regions of the transistor TRN11. Here, these source and drain regions are N⁺ doped regions formed within an underlying substrate or well of the P type.

The insulating region 2 is locally separated into two insulating areas 20 and 21 by the separation region 11 which is here also a N⁺ doped region opening into the underlying substrate of the P type.

In the example described here, the polysilicon central part 120 of the outgrowth (second electrode of the capacitive structure) partially covers the separation region 11 and is separated from the latter by the gate oxide layer.

The ring oscillator also comprises, on the left-hand side of FIG. 5, a region ZG0 also doped N⁺ which contacts the source region of the transistor TRN11. The separation region 11, one part of which is situated under the part 120 made of polysilicon, is extended on the left in order to come into contact with the region ZG0. As will be seen in more detail with reference to FIG. 6, this region ZG0 is designed to be connected to ground GND via contact lugs CTCO.

A region ZG1, doped N⁺, situated on the right-hand side of FIG. 5, is analogous to the region ZG0 and will allow, as will be seen with reference to FIG. 6, the sources of the NMOS transistors TRN41-TRN44 together with the extended corresponding separation regions 11 to be connecter to ground via contact lugs CTC2.

In order to enable these connections to ground GND to be made, power supply rails, formed for example at the first metallization level of the integrated circuit and referenced RZG0 and RZG1, cover the corresponding regions ZG0 and ZG1 and are connected to them by the corresponding contact lugs (FIG. 6). The rails RZG0 and RZG1 are designed to be connected to ground GND.

In order to connect the central part 120 (second electrode) of the capacitive structure to the power supply voltage Vdd, an interconnection region 220, also made of polysilicon, is formed on top of the insulating region 2 limiting the active region of the PMOS transistor TRP21.

It should be noted here that the two polysilicon regions 120 and 220 are formed simultaneously with the gate regions of the transistors by means of the “poly” mask.

A region ZD1 runs along the transistors TRP21-TRP24 and will enable, as will be seen in more detail with reference to FIG. 6, notably the sources of the PMOS transistors to be connected to the power supply voltage Vdd via contact lugs CTC1.

In order to enable this connection to the power supply voltage Vdd to be made, a power supply rail, formed for example at the first metallization level of the integrated circuit and referenced RZD1, covers the region ZD1 and is connected to it via the corresponding contact lugs (FIG. 6). The rail RZD1 is designed to be connected to the power supply voltage Vdd.

Furthermore, in this embodiment, a contact CTC connected, on the one hand, to the region of polysilicon 220 and, on the other, to a metallization MTL coming into contact with the rail RZD1, is provided in such a manner as to connect the regions of polysilicon 220, and consequently the corresponding regions of polysilicon 120, in other words the second electrodes of the capacitive structures, to the voltage Vdd.

It should be noted that the connection to ground of the separation regions 11 is carried out by simply extending these active regions as far as the regions ZG0 and ZG1 already present within the layout of the conventional oscillator (not equipped with the decoupling capacitive structures), whereas the connection to the voltage Vdd of the second electrodes of the capacitive structures requires the formation of the regions of polysilicon 220 and of the metallization MTL in order to come into contact with the rail RZD1.

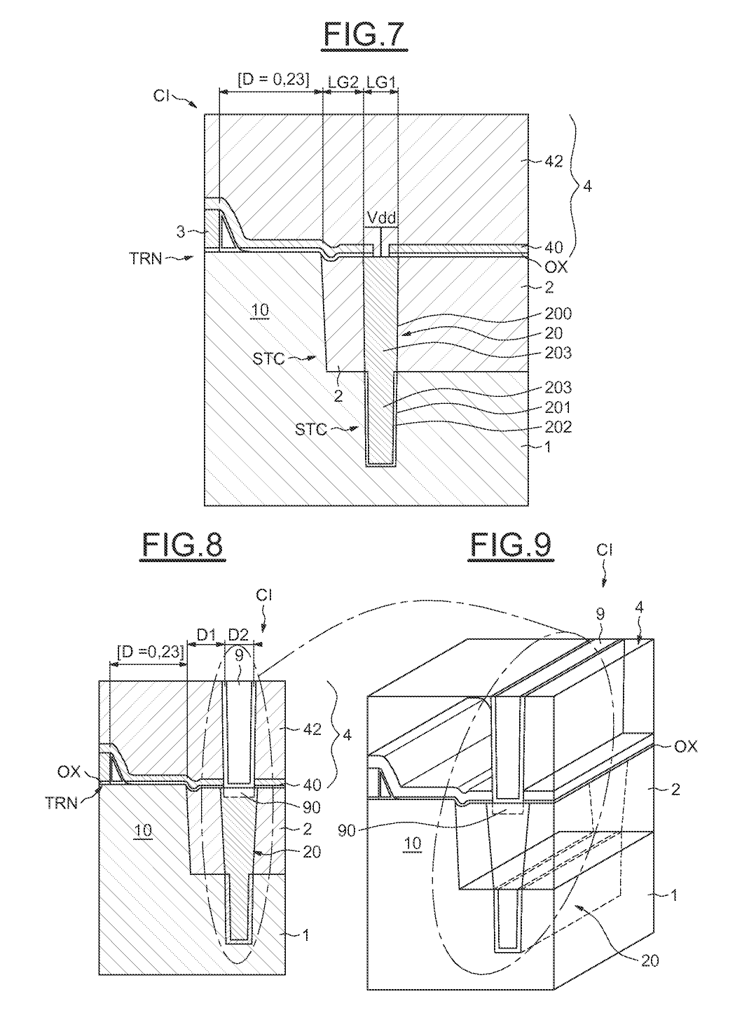

Reference will now more particularly be made to FIGS. 7 to 16 in order to illustrate another variant.

In this variant, the substrate forms the first electrode and the second electrode of the capacitive structure comprises an electrically-conducting trench situated at least within the insulating region limiting the active region of the transistor, this electrically-conducting trench containing an internal area configured in order to allow a reduction of compressive stress within the active region, the second electrode here again being separated from the first electrode by a dielectric material.

More precisely, with respect to the transistor TRN in FIG. 1, the transistor TRN according to the embodiment illustrated in FIG. 7 comprises a trench 20 here having an upper part 200 situated in the insulating region 2 and extended by a lower part 201 situated in the underlying substrate 1 forming the first electrode of the capacitive structure STC, for example connected to ground GND.

Furthermore, in this example, the internal walls of the lower part 201 of the trench are coated with an electrically-insulating layer 202, for example of silicon dioxide.

The internal area of the trench thus formed contains polycrystalline silicon or polysilicon 203.

The upper face of the trench 20 is situated substantially at the same level as the upper face of the active region 10.

This trench is electrically active because it forms the second electrode of the capacitive structure STC and it is electrically connected here to the voltage Vdd.

This trench 20 also has a mechanical function allowing a reduction of compressive stresses within the active region 10. This is because, in this embodiment, the polysilicon 202, which is initially deposited in amorphous form, re-crystallizes during the cooling step to become a material under tensile stress, which reduces the compressive stresses notably within the insulating region 2 and which consequently allows the compressive stresses within the active region 10 to be reduced. Furthermore, such an embodiment offers a thermo-mechanical advantage. The reason for this is that the silicon and the polysilicon exhibit identical thermal expansion coefficients and this results in lower stresses within the active region when the temperature undergoes changes linked to the environment of the product incorporating the integrated circuit.

Although in the embodiment in FIG. 7 the trench 20 extends into the underlying substrate, it would have been possible for the trench 20 to only be situated within the insulating region 2 without overspilling into the underlying substrate. Moreover, with such an embodiment, a reduction of around 15% in the compressive stresses is obtained with respect to the transistor in FIG. 1.

However, the lower part of the trench 20 situated within the underlying substrate also contributes to the reduction in the compressive stresses within the active region 10. Thus, the embodiment in FIG. 7 allows a reduction of 30% in the compressive stresses within the active region with respect to the transistor in FIG. 1.

In the upper part, the decoupling capacitor is formed between the polysilicon 203 and the active region 10, the portion of insulating region situated between these two electrodes forming the dielectric of the capacitor.

In the lower part, the decoupling capacitor is formed between the polysilicon 203 and the substrate 1, the insulating layer 202 forming the dielectric of the capacitor.

Furthermore, this layer 202 prevents a direct contact between the silicon of the substrate and the polysilicon 203 of the trench, which avoids the creation of localized defects in the silicon able to lead to the generation of dislocations.

Here, the width LG1 of the trench 20 is equal to the critical dimension CD of the technology in question, in the present case 0.15 micrometers. This critical dimension is the minimum dimension of a line of active region.

The distance LG2 between the edge of the trench 20 and the edge of the active region 10 here is equal to a minimum distance defined by the design rules (DRM: Design Rules Manual) of the technology in question, in this case 0.05 micrometers for a 90 nanometer technology.

Whereas, in this embodiment, the substrate and the active region 10 are connected to ground GND, the other electrode of the capacitor is connected to the power supply voltage Vdd. For this purpose, an orifice is formed in the layer 40 in order to allow the application of this voltage Vdd.

This representation in FIG. 7 is schematic. One way of making this connection to the power supply voltage Vdd is illustrated more particularly in FIGS. 8 and 9.

In these embodiments, the electrical connection to the second electrode 20 of the capacitive structure is obtained by a metal contact 9 passing through the additional insulating region 4 to potentially penetrate into the inside of the trench 20 (part 90 shown with a dashed line in these figures).

D1 (FIG. 8) denotes the minimum distance between the contact region 9 and the edge of the active region.

D2 denotes the minimum width of a contact region 9.

It should be noted here that such a metal contact also allows a relaxation of the stresses in the active region 10 of the transistor TRN. However, the inventors have observed that even if the metal contact 9 does not pass through the insulating region 4, and notably the CESL layer 40, without penetrating into the trench 20, a relaxation of the compressive stresses in the active region 10 of the transistor TRN is nevertheless obtained with respect to the compressive stresses in the region 10 of the transistor TRN in FIG. 1.

Moreover, this is true whether the layer 40 is a layer in compression or a layer in tension because, in the latter case, the material used for the contact region 9 is generally a material itself under tensile stress. The inventors have additionally observed that the combination of a layer 40 in tension through which a contact region itself in tension allowed the tensile stress in the channel region to be increased, which itself allows the mobility of the electrons to be increased.

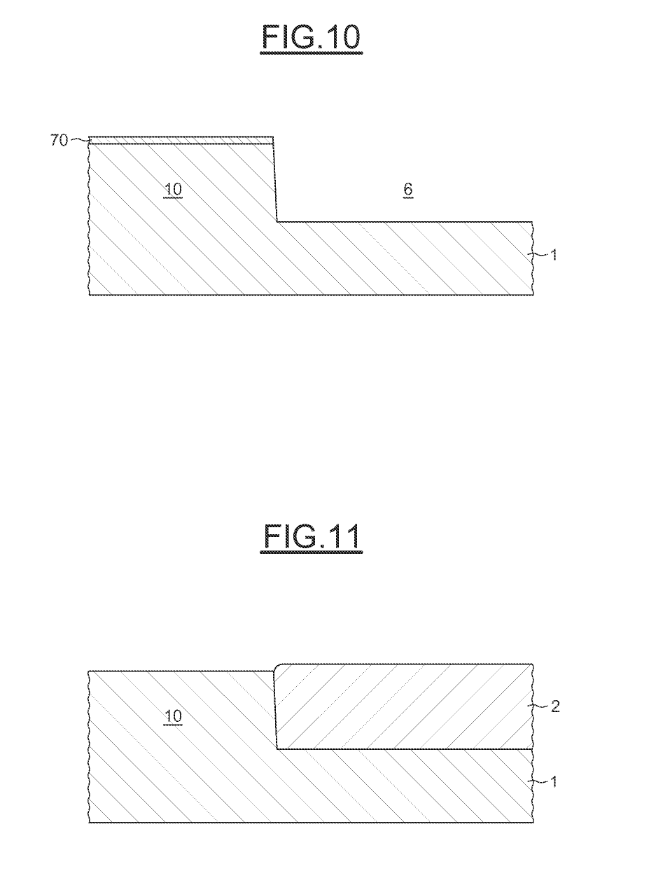

Reference is now more particularly made to FIGS. 10 to 13 in order to illustrate one embodiment of a method allowing the formation of the trench 20.

More precisely, after having deposited onto the substrate 1 a bilayer 70 (silicon oxide/silicon nitride) on which is a layer of photoresist which is exposed through a mask called “active mask or active region mask”, which will allow the contours of the insulating region 2 to be determined and consequently those of the active region, after development of the resist an etch of the bilayer 70 and of the substrate 1 is carried out using the remaining part of the resist as a hard mask in such a manner as to obtain a trench 6 (FIG. 10) which will be filled with insulating material so as to form, after chemical-mechanical polishing and removal of the silicon nitride, the insulating region 2 (FIG. 11).

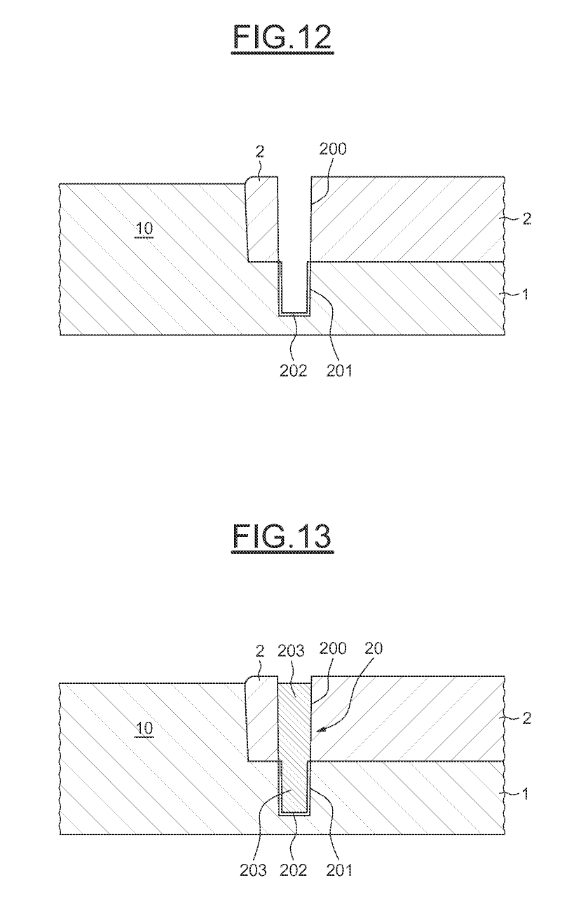

Then, as illustrated in FIG. 12, an etch of a first trench is carried out so as to define the upper part 200 and the upper part 201 and a re-oxidation of the lower part 201 of this first trench is carried out in order to form the electrically-insulating layer 202.

At this stage, a trench is therefore obtained, that will be referred to here as initial trench.

Then, this initial trench is filled with polysilicon deposited in the amorphous state at high temperature, the latter being transformed, during the cooling step, into polycrystalline silicon, then etched for example by chemical-mechanical polishing or by dry etching (FIG. 13).

Once these operations have been carried out, the other operations for fabricating the integrated circuit are carried out in a conventional manner known per se, notably the formation of the gate regions of the transistors and the formation of the insulating region 4.

With regard to the formation of the metal contact 9, the latter is formed in an manner analogous to the metal contacts designed to come into contact with the source, drain and gate regions of the transistor in order to connect them to a metallization level of the interconnection part (BEOL: Back End Of Line) of the integrated circuit.

The location and the geometry of the contact 9 are defined on the “contacts” mask.

However, the use of metal contacts coming into contact with the trench 20 or even penetrating into this trench, is not always possible.

Indeed, the dimensional constraints to be complied with for the formation of a metal contact with respect to the edge of the active region can be more severe than those governing the formation of the trench 20.

The dimensions D1 and D2, notably, are used automatically in the computerized tool for generation of the “contacts” mask for determining as a function of the locations of the various actives regions 10 and trenches 20, but also as a function of the distance with respect to a potential neighboring region of polysilicon and/or of the presence or absence of a metal line at a higher metallization level, the possible localizations of the contact region or regions 9 coming into contact with or penetrating into these trenches, together with the geometries and dimensions of the contact region or regions.

The above is carried out automatically without intervention of the designer of the circuit and in a totally transparent manner for him/her.

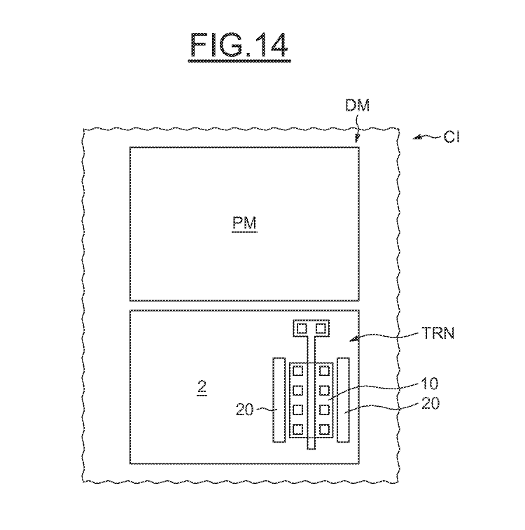

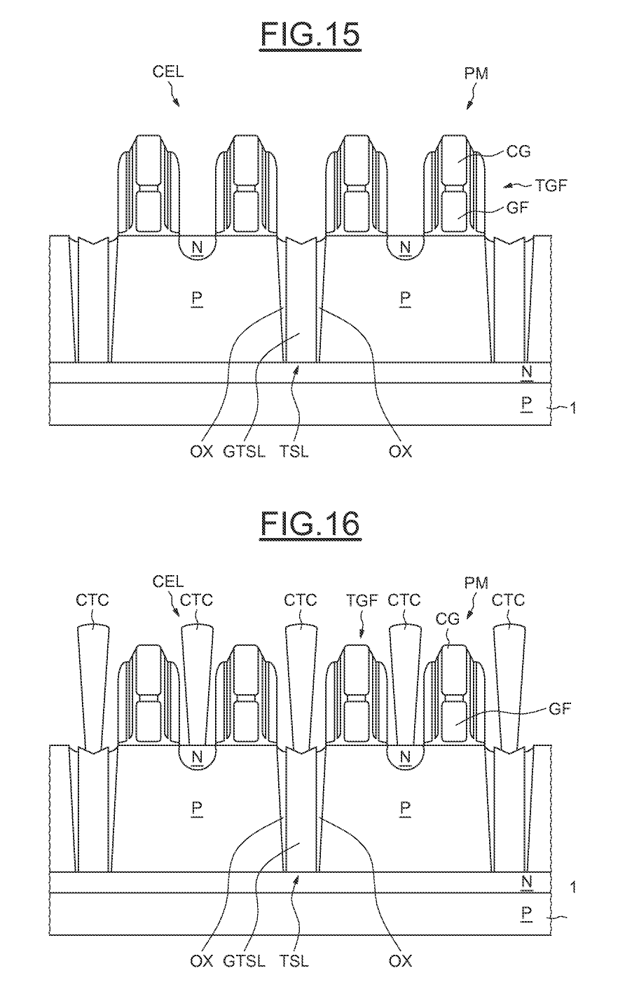

Reference will now more particularly be made to FIGS. 14 to 16 in order to illustrate one application of the invention to an integrated circuit comprising a memory device whose memory plane PM comprises, as illustrated in FIG. 15, non-volatile memory cells CEL and selection transistors with buried gate TSL.

More precisely, each memory cell CEL comprises a transistor with floating gate TGF formed in and on a semiconductor well of the P type separated from an underlying substrate of the P type by a semiconductor layer of the N type. Conventionally, each floating-gate transistor comprises a floating gate GF, for example made of polysilicon, and a control gate CG.

Each selection transistor TSL, allowing a row of cells to be selected, is an MOS transistor whose gate GTSL is a gate buried in the well of the P type and electrically isolated from this well by a gate oxide OX, typically silicon dioxide. The buried layer of the N type forms the source regions of the selection transistors TSL. It should be noted that the buried gate GTSL is common to the two adjacent selection transistors TSL whose two gate oxides OX are respectively situated on the two sides of this buried gate.

As is conventional in this field and is illustrated schematically in FIG. 14, the memory device DM integrated into the integrated circuit CI comprises, aside from the memory plane PM formed of the matrix of memory cells CL, a control block or logic notably comprising the line decoders and column decoders. All these elements of the control block BLC notably comprise NMOS transistors TRN.

Furthermore, whereas owing to the density of the memory plane, it may not be envisaged for trenches 20 to be disposed inside of the memory plane, but also around this memory plane so as to avoid edge effects, it is perfectly advantageous, as illustrated in FIG. 14, to associate with at least some of the NMOS transistors trenches 20 that may in certain cases be situated on either side of at least some of these NMOS transistors TRN, in such a manner as to create capacitive structures.

The formation of the trenches 20 of the transistors TRN is carried out simultaneously with the formation of the buried gates GTSL of the selection transistors TSL of the memory plane. Indeed, the etching of the trenches designed to receive the buried gates of these transistors and the etching of the first trenches in the insulating region around the transistors TRN and within the underlying substrate are carried out simultaneously and the definition of the locations of these first trenches is defined on the same mask as that enabling the definition of the trenches designed to receive the buried gates. Moreover, this is totally transparent for the designer of the integrated circuit because the locations of the first trenches destined to become the trenches 20 are defined within the insulating regions 2.

The depths of the first trenches and of those designed to receive the buried gates GTSL are substantially identical.

Furthermore, the oxidation of the internal walls of all these trenches leads, on the one hand, to the formation of the gate oxide of the selection transistors and, on the other, to the formation of the insulating layer 202.

Finally, all these trenches are filled with polysilicon.

As illustrated in FIG. 16, contacts CTC are made on various regions of the memory cells of the memory plane PM. Then, by analogy to what has been described hereinbefore, the formation of these contacts CTC is advantageously carried out simultaneously with the contact regions 9 associated with the transistor TRN using the “contacts” mask, which allows the second electrodes of the capacitive structures to be biased.

What is claimed is:

1. An integrated circuit, comprising:
a substrate;
at least one component disposed at least partially within an active region of the substrate limited by an insulating region;
a capacitive structure having a first electrode configured to be connected to a first potential and a second electrode configured to be connected to a second potential,
wherein at least one of the first and second electrodes of the capacitive structure is situated at least, in part, within the insulating region.

2. The integrated circuit according to claim 1, wherein the other of the first and second electrodes is formed by a part of the substrate.

3. The integrated circuit according to claim 1, wherein the other of the first and second electrodes is contained within a volume situated on top of the insulating region.

4. The integrated circuit according to claim 1, wherein the component is a component detrimentally sensitive to the compressive stresses.

5. The integrated circuit according to claim 4, wherein the component is an NMOS transistor.

6. The integrated circuit according to claim 1, wherein the first potential is ground and the second potential is a power supply voltage of the integrated circuit.

7. The integrated circuit according to claim 1, further comprising an additional insulating region disposed above the component, the active region and the insulating region, and wherein the first electrode comprises a first region formed by a part of the substrate and locally separating said insulating region into two insulating areas and the second electrode comprises a second electrically-conducting region situated within the additional insulating region on top of said separation region, the two electrodes being separated by a layer of a dielectric material.

8. The integrated circuit according to claim 7, wherein the second region comprises polysilicon.

9. The integrated circuit according to claim 7, wherein said first region has an upper face situated substantially at the same level as said upper face of the active region and opens into a lower region of the substrate.

10. The integrated circuit according to claim 7, wherein the insulating area situated nearest to said active region has a volume less than or equal to that of the insulating area furthest from the active region.

11. The integrated circuit according to claim 7, wherein said layer of dielectric material comprises a portion of a gate oxide layer for a MOS transistor.

12. The integrated circuit according to claim 11, wherein said second region has a structure made of a same material as a gate region of a MOS transistor.

13. The integrated circuit according to claim 1, wherein the substrate forms the first electrode and the second electrode comprises an electrically-conducting trench situated at least within said insulating region and containing an internal area configured in order to allow a reduction in compressive stresses in said active region, the second electrode being separated from the first electrode by a dielectric material.

14. The integrated circuit according to claim 13, wherein said at least one trench has an upper part situated in said insulating region, and extended by a lower part situated in the substrate and separated from the substrate by a layer of dielectric material, the internal area being situated in said upper part and in said lower part.

15. The integrated circuit according to claim 13, wherein the internal area contains polycrystalline silicon.

16. The integrated circuit according to claim 13, comprising a memory device comprising a memory plane having non-volatile memory cells and selection transistors with buried gates, together with a control block for the memory plane comprising NMOS transistors, said at least one electrically-conducting trench being situated in at least the insulating region limiting the active region of at least one of these NMOS transistors of the control block and having a depth substantially equal to that of the buried gates.

17. An integrated circuit, comprising:
a substrate;
a circuit component disposed within an active region of the substrate limited by both a separation region and an insulating region;
wherein the separation region is separated from the insulating region by a portion of the substrate; and
a capacitive structure having a first electrode formed by said portion of the substrate and configured to be connected to a first potential; a dielectric layer on a top surface of said portion of the substrate; and a second electrode on top of the dielectric layer and configured to be connected to a second potential.

18. The integrated circuit of claim 17, wherein the circuit component is a MOS transistor.

19. An integrated circuit, comprising:
a substrate;
a circuit component disposed within an active region of the substrate limited by an insulating region;
wherein the insulation region includes a trench extending with a depth reaching the substrate; and
a capacitive structure having a first electrode formed by said substrate and configured to be connected to a first potential; a dielectric layer; and a second electrode formed by material which fills said trench in the insulation region and configured to be connected to a second potential.

20. The integrated circuit of claim 19, wherein the circuit component is a MOS transistor.

21. The integrated circuit of claim 19, wherein said trench in the insulating region further extends into the substrate below the insulating region, said dielectric layer lining walls of the trench extension in the substrate, said material of the second electrode further filling the trench extension.

22. An integrated circuit, comprising:
a substrate;
at least one component disposed at least partially within an active region of the substrate limited by an insulating region;
a capacitive structure having a first electrode configured to be connected to a ground voltage potential and a second electrode configured to be connected to a power supply voltage potential,
wherein at least one of the first and second electrodes of the capacitive structure is situated at least, in part, within the insulating region.

23. An integrated circuit, comprising:
a substrate;
a MOS transistor disposed at least partially within an active region of the substrate limited by a first insulating region, said MOS transistor having a gate;
a second insulating region disposed above the MOS transistor, the active region and the first insulating region;
a capacitive structure having a first electrode and a second electrode, the first and second electrodes separated by a layer of a dielectric material;
wherein the first electrode comprises a first electrically-conducting region formed by a part of the substrate and wherein the second electrode comprises a second electrically-conducting region situated within the second insulating region;
wherein said second electrically-conducting region has a structure made of a same material as the gate of the MOS transistor; and
wherein the second electrode comprises an electrically-conducting trench situated at least within said first insulating region and containing an internal area configured in order to allow a reduction in compressive stresses in said active region.
